(19) United States
(12) Patent Application Publication
(10) Pub. No.: US 2006/0261912 A1
(43) Pub. Date: Nov. 23, 2006

(54) Radio frequency switching circuit and semiconductor device including the same

(75) Inventors: Masashi Miyagi, Osaka (JP); Tadayoshi Nakatsuka, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/438,280

(22) Filed: May 23, 2006

(30) Foreign Application Priority Data
May 23, 2005 (JP) 2005-149767

(51) Int. Cl. H01P 1/15; H03K 17/00

(52) U.S. Cl. 333/103; 327/416

(57) ABSTRACT

A radio frequency switching circuit having improved input/output power characteristics is provided. The circuit includes basic switching sections each including a plurality of FETs 13a-13d, 14a-14d, 11a-11d or 12a-12d connected in series. The basic switching sections are respectively provided between an input/output terminal 1 and the ground, between an input/output terminal 3 and the ground, between the input terminals 1 and 2, and between the input terminals 2 and 3. The circuit also includes a plurality of resistors 43a-43d, 44a-44d, 41a-41d and 42a-42d, each having one terminal connected to a drain electrode of a corresponding FET and the other terminal connected to a source electrode of the corresponding FET. A resistor connected between the drain and source electrodes of an FET, among the FETs included in a basic switching section in an OFF state, closer to the input/output terminal to which a signal is inputted has a smaller resistance value.

### BACKGROUND OF THE INVENTION

1. Field of the Invention

The present invention relates to a radio frequency switching circuit, and more specifically to a radio frequency switching circuit using a field effect transistor.

2. Description of the Background Art

In recent years, as wireless terminals and the like have rapidly prevailed and enhanced, radio frequency switching circuits used in the wireless terminals and the like now require having low-loss and low-distortion characteristics. Under such circumstances, radio frequency switching circuits including field effect transistors (hereinafter, referred to as “FETS”) connected in a plurality of stages have been conventionally proposed. One example of such radio frequency switching circuits is described in Japanese Laid-Open Patent Publication No. 2000-277703.

FIG. 16 shows a radio frequency switching circuit described in Japanese Laid-Open Patent Publication No. 2000-277703. The radio frequency switching circuit shown in FIG. 16 comprises a first input/output terminal A, a second input/output terminal B, a third input/output terminal C, shunt FETs 161, transfer FETs 162, control terminals D and E, and inter-stage potential fixing resistors Ra. The circuit can be divided into a shunt basic switching section including the shunt FETs 161 connected in a plurality of stages and a transfer basic switching section including the transfer FETs 162 connected in a plurality of stages.

Regarding the radio frequency switching circuit shown in FIG. 16, a path passing through the shunt basics witching section from the first input/output terminal A to the second input/output terminal B is referred to as a “shunt path”. A path passing through the transfer basic switching section from the first input/output terminal A to the third input/output terminal C is referred to as a “transfer path”. For transmitting a signal through the transfer path, a High voltage V2 is applied to the control terminal E, and a Low voltage V1 is applied to the control terminal D. Thus, the transfer FETs 162 are turned ON and the shunt FETs 161 are turned OFF. As a result, a transmission signal which is inputted to the first input/output terminal A is outputted from the third input/output terminal C.

In the radio frequency switching circuit shown in FIG. 16, the shunt path and the transfer path each include a plurality of stages of FETs connected in series. Thus, an input signal divided into the number of the stages is applied to each of the FETs included in the path in an OFF state. Therefore, as the number of the stages of FETs is larger, the FETs are more easily maintained in an OFF state. As a result, a more superb distortion characteristic and a higher input/output power characteristic are provided than in a circuit including one stage of FET.

The inter-stage potential fixing resistors Ra, which are each connected between a drain electrode and a source electrode of the corresponding FET in each path, are provided for fixing the inter-stage potentials between the FETs connected in the plurality of stages to an equal level. Usually, as the inter-stage potential fixing resistors Ra, resistors having a high resistance value of about 50 kΩ are used. By fixing the inter-stage potentials between the FETs connected in the plurality of stages to an equal level, an equally divided signal voltage can be applied to the FETs in an OFF state, and thus the FETs are easily maintained in an OFF state. In general, all of the inter-stage potential fixing resistors Ra have an equal resistance value.

In actuality, however, the inter-stage potentials between the plurality of FETs in an OFF state cannot be at an equal level merely by connecting a resistor having a high resistance value to each FET in parallel. Rather, a signal voltage applied to an FET closer to the input/output terminal, to which the signal is inputted, is higher than a signal voltage applied to an FET farther from the input/output terminal.

FIG. 17 shows a time-wise change of the voltage between the gate electrode and the source electrode of each FET in a path in an OFF state when a signal having a frequency of 1 GHz is inputted to a radio frequency switching circuit having a structure shown in FIG. 16 with four stages of FETs. As shown in FIG. 17, the voltage amplitude between the gate electrode and the source electrode and the DC potential are different among the FETs in a path in an OFF state. The difference is larger as the number of stages is larger. This indicates that among the FETs in the path in an OFF state, FETs closer to the input/output terminal to which the signal is inputted are more likely to be turned ON. This causes a problem that when a high power signal is transmitted through one of the paths, the signal is likely to leak to the other path in an OFF state. Such a leak of the signal to the path in an OFF state deteriorates the radio frequency characteristics including insertion loss and distortion characteristics.

### SUMMARY OF THE INVENTION

Therefore, an object of the present invention is to provide a radio frequency switching circuit having improved radio frequency characteristics by applying an equal signal voltage to FETs in a path in an OFF state.

The present invention has the following features to attain the object mentioned above.

A first aspect of the present invention is directed to a radio frequency switching circuit for controlling a flow of a radio frequency signal, comprising a basic switching section including a plurality of field effect transistors connected in series and provided between an input/output terminal for inputting and outputting the radio frequency signal and the ground; and a plurality of resistor elements each having one terminal connected to a drain electrode of a corresponding field effect transistor among the plurality of field effect transistors and having the other terminal connected to a source electrode of the corresponding field effect transistor. A resistor among the plurality of resistors which is connected between the drain electrode and the source electrode of a field effect transistor, among the plurality of field effect transistors, which is connected to the input/output terminal has a resistance value smaller than that of the resistor connected between the drain electrode and the source electrode of each of the remaining field effect transistors.

In this case, the basic switching section may include nnumber of field effect transistors (n is an integer of 2 or greater) connected in series; and expression Rds(1)<Rds(2)≦ . . . ≦Rds(n-1)≦Rds(n) may be fulfilled where Rds(i) is the resistance value of the resistor connected between the drain electrode and the source electrode of the i'th field effect transistor (i is an integer of 1 or greater and n or smaller) from the input/output terminal.

A second aspect of the present invention is directed to a radio frequency switching circuit for controlling a flow of a radio frequency signal, comprising a basic switching section including a plurality of field effect transistors connected in series and provided between an input/output terminal for inputting and outputting the radio frequency signal and the ground; and a plurality of capacitors each having one terminal connected to a drain electrode of a corresponding field effect transistor among the plurality of field effect transistors and having the other terminal connected to a source electrode of the corresponding field effect transistor. A capacitor among the plurality of capacitors which is connected between the drain electrode and the source electrode of a field effect transistor, among the plurality of field effect transistors, which is connected to the input/output terminal has a capacitance value larger than that of the capacitor connected between the drain electrode and the source electrode of each of the remaining field effect transistors.

In this case, the basic switching section may include n number of field effect transistors (n is an integer of 2 or greater) connected in series; and expression Cds(1)>Cds(2)≧ . . . ≧Cds(n-1)≧Cds(n) may be fulfilled where Cds(i) is the capacitance value of the capacitor connected between the drain electrode and the source electrode of the i'th field effect transistor (i is an integer of 1 or greater and n or smaller) from the input/output terminal.

A third aspect of the present invention is directed to a radio frequency switching circuit for controlling a flow of a radio frequency signal, comprising a basic switching section including a plurality of field effect transistors connected in series and provided between input/output terminals for inputting and outputting the radio frequency signal; and a plurality of resistors each having one terminal connected to a drain electrode of a corresponding field effect transistor among the plurality of field effect transistors and having the other terminal connected to a source electrode of the corresponding field effect transistor. Where an input/output terminal, among the input/output terminals, to which a signal voltage is inputted when the basic switching section is in an OFF state is an off-time active terminal, a resistor among the plurality of resistors which is connected between the drain electrode and the source electrode of a field effect transistor, among the plurality of field effect transistors, which is connected to the off-time active terminal has a resistance value smaller than that of the resistor connected between the drain electrode and the source electrode of each of the remaining field effect transistors.

In this case, the basic switching section may include n number of field effect transistors (n is an integer of 2 or greater) connected in series; and expression Rds(1)<Rds(2)≦ . . . ≦Rds(n-1)≦Rds(n) may be fulfilled where Rds(i) is the resistance value of the resistor connected between the drain electrode and the source electrode of the i'th field effect transistor (i is an integer of 1 or greater and nor smaller) from the off-time active terminal.

A fourth aspect of the present invention is directed to a radio frequency switching circuit for controlling a flow of a radio frequency signal, comprising a basic switching section including a plurality of field effect transistors connected in series and provided between input/output terminals for inputting and outputting the radio frequency signal; and a plurality of capacitors each having one terminal connected to a drain electrode of a corresponding field effect transistor among the plurality of field effect transistors and having the other terminal connected to a source electrode of the corresponding field effect transistor. Where an input/output terminal, among the input/output terminals, to which a signal voltage is inputted when the basic switching section is in an OFF state is an off-time active terminal, a capacitor among the plurality of capacitors which is connected between the drain electrode and the source electrode of a field effect transistor, among the plurality of field effect transistors, which is connected to the off-time active terminal has a capacitance value larger than that of the capacitor connected between the drain electrode and the source electrode of each of the remaining field effect transistors.

In this case, the basic switching section may include n number of field effect transistors (n is an integer of 2 or greater) connected in series; and expression Cds(1)>Cds(2)≧ . . . ≧Cds(n-1)≧Cds(n) may be fulfilled where Cds(i) is the capacitance value of the capacitor connected between the drain electrode and the source electrode of the i'th field effect transistor (i is an integer of 1 or greater and nor smaller) from the off-time active terminal.

A fifth aspect of the present invention is directed to a radio frequency switching circuit for controlling a flow of a radio frequency signal, comprising a basic switching section including at least one multi-gate field effect transistor and provided between an input/output terminal for inputting and outputting the radio frequency signal and the ground; and a plurality of resistors each having one terminal connected to a drain electrode or a source electrode of a corresponding multi-gate field effect transistor among the at least one multi-gate field effect transistor and having the other terminal connected to a corresponding inter-gate electrode mesa among a plurality of inter-gate electrode mesas of the at least one multi-gate field effect transistor. A resistor among the plurality of resistors which is connected to an inter-gate electrode mesa, among the plurality of inter-gate electrode mesas, which is located closest to the input/output terminal has a resistance value smaller than that of the resistor connected to each of the remaining inter-gate electrode mesas.

In this case, the basic switching section may include the at least one multi-gate field effect transistor each including n number of gate electrodes (n is an integer of 2 or greater); and expression Rms(1)<Rms(2)≦ . . . ≦Rms(n-1)≦Rms(n) may be fulfilled where Rms(i) is the resistance value of the resistor connected to the i'th inter-gate electrode mesa (i is an integer of 1 or greater and n or smaller) from the input/output terminal.

A sixth aspect of the present invention is directed to a radio frequency switching circuit for controlling a flow of a radio frequency signal, comprising a basic switching section including at least one multi-gate field effect transistor and provided between an input/output terminal for inputting and outputting the radio frequency signal and the ground; and a plurality of capacitors each having one terminal connected to a drain electrode or a source electrode of a corresponding multi-gate field effect transistor among the at least one multi-gate field effect transistor and having the other terminal connected to a corresponding inter-gate electrode mesa among a plurality of inter-gate electrode mesas of the at least one multi-gate field effect transistor. A capacitor among the plurality of capacitors which is connected to an inter-gate electrode mesa, among the plurality of inter-gate electrode mesas, which is located closest to the input/output terminal has a capacitance value larger than that of the capacitor connected to each of the remaining inter-gate electrode mesas.

In this case, the basic switching section may include the at least one multi-gate field effect transistor each including n number of gate electrodes (n is an integer of 2 or greater); and expression Cms(1)>Cms(2)≧ . . . ≧Cms(n-1)≧Cms(n) may be fulfilled where Cms(i) is the capacitance value of the capacitor connected to the i'th inter-gate electrode mesa (i is an integer of 1 or greater and n or smaller) from the input/output terminal.

A seventh aspect of the present invention is directed to a radio frequency switching circuit for controlling a flow of a radio frequency signal, comprising a basic switching section including at least one multi-gate field effect transistor and provided between input/output terminals for inputting and out putting the radio frequency signal; and a plurality of resistors each having one terminal connected to a drain electrode or a source electrode of a corresponding multi-gate field effect transistor among the at least one multi-gate field effect transistor and having the other terminal connected to a corresponding inter-gate electrode mesa among a plurality of inter-gate electrode mesas of the at least one multi-gate field effect transistor. Where an input/output terminal, among the input/output terminals, to which a signal voltage is inputted when the basic switching section is in an OFF state is an off-time active terminal, a resistor among the plurality of resistors which is connected to an inter-gate electrode mesa, among the plurality of inter-gate electrode mesas, which is located closest to the off-time active terminal has a resistance value smaller than that of the resistor connected to each of the remaining inter-gate electrode mesas.

In this case, the basic switching section may include the at least one multi-gate field effect transistor each including n number of gate electrodes (n is an integer of 2 or greater); and expression Rms(1)<Rms(2)≦ . . . ≦Rms(n-1)≦Rms(n) may be fulfilled where Rms(i) is the resistance value of the resistor connected to the i'th inter-gate electrode mesa (i is an integer of 1 or greater and n or smaller) from the off-time active terminal.

An eighth aspect of the present invention is directed to a radio frequency switching circuit for controlling a flow of a radio frequency signal, comprising a basic switching section including at least one multi-gate field effect transistor and provided between input/output terminals for inputting and outputting the radio frequency signal; and a plurality of capacitors each having one terminal connected to a drain electrode or a source electrode of a corresponding multi-gate field effect transistor among the at least one multi-gate field effect transistor and having the other terminal connected to a corresponding inter-gate electrode mesa among a plurality of inter-gate electrode mesas of the at least one multi-gate field effect transistor. Where an input/output terminal, among the input/output terminals, to which a signal voltage is inputted when the basic switching section is in an OFF state is an off-time active terminal, a capacitor among the plurality of capacitors which is connected to an inter-gate electrode mesa, among the plurality of inter-gate electrode mesas, which is located closest to the off-time active terminal has a capacitance value larger than that of the capacitor connected to each of the remaining inter-gate electrode mesas.

In this case, the basic switching section may include the at least one multi-gate field effect transistor each including n number of gate electrodes (n is an integer of 2 or greater); and expression Cms(1)>Cms(2)≧ . . . ≧Cms(n-1)≧Cms(n) may be fulfilled where Cms (i) is the capacitance value of the capacitor connected to the i'th inter-gate electrode mesa (i is an integer of 1 or greater and n or smaller) from the off-time active terminal.

A ninth aspect of the present invention is directed to a radio frequency switching circuit, comprising a combination of any identical or different radio frequency switching circuits described above. The flow of a radio frequency signal is optionally switched between a plurality of input/output terminals.

A tenth aspect of the present invention is directed to a semiconductor device, comprising any radio frequency switching circuit described above integrated on a semiconductor substrate.

A radio frequency switching circuit and a semiconductor device including the same according to the present invention can improve input/output power characteristics over the conventional radio frequency switching circuit by connecting resistors having different resistance values or capacitors having different capacitor values between a drain electrode and a source electrode of each of field effect transistors connected in a plurality of stages (or between an inter-gate electrode mesa and a source electrode of at least one multi-gate field effect transistor).

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of a radio frequency switching circuit according to a first embodiment of the present invention;

FIG. 2 shows a characteristic of the voltage between the gate electrode and the source electrode of an FET in an OFF state when a radio frequency signal is inputted to the radio frequency switching circuit shown in FIG. 1;

FIG. 3 shows the dependence on the input power of the insertion loss of the radio frequency switching circuit shown in FIG. 1;

FIG. 4 shows the dependence on the input power of the second-harmonic distortion of the radio frequency switching circuit shown in FIG. 1;

FIG. 5 shows the dependence on the input power of the third-harmonic distortion of the radio frequency switching circuit shown in FIG. 1;

FIG. 6 is a circuit diagram of a radio frequency switching circuit according to a second embodiment of the present invention;

FIG. 7 shows the dependence on the input power of the insertion loss of the radio frequency switching circuit shown in FIG. 6;

FIG. 8 shows the dependence on the input power of the second-harmonic distortion of the radio frequency switching circuit shown in FIG. 6;

FIG. 9 shows the dependence on the input power of the third-harmonic distortion of the radio frequency switching circuit shown in FIG. 6;

FIG. 10 is a circuit diagram of a radio frequency switching circuit according to a third embodiment of the present invention;

FIG. 11 shows the dependence on the input power of the insertion loss of the radio frequency switching circuit shown in FIG. 10;

FIG. 12 shows the dependence on the input power of the second-harmonic distortion of the radio frequency switching circuit shown in FIG. 10;

FIG. 13 shows the dependence on the input power of the third-harmonic distortion of the radio frequency switching circuit shown in FIG. 10;

FIG. 14 shows a structure of single-gate FETs connected in two stages;

FIG. 15 shows a structure of a multi-gate FET;

FIG. 16 is a circuit diagram of a conventional radio frequency switching circuit; and

FIG. 17 shows a characteristic of the voltage between the gate electrode and the source electrode of an FET in an OFF state when a radio frequency signal is inputted to the conventional radio frequency switching circuit.

### DESCRIPTION OF THE PREFERRED EMBODIMENTS

### First Embodiment

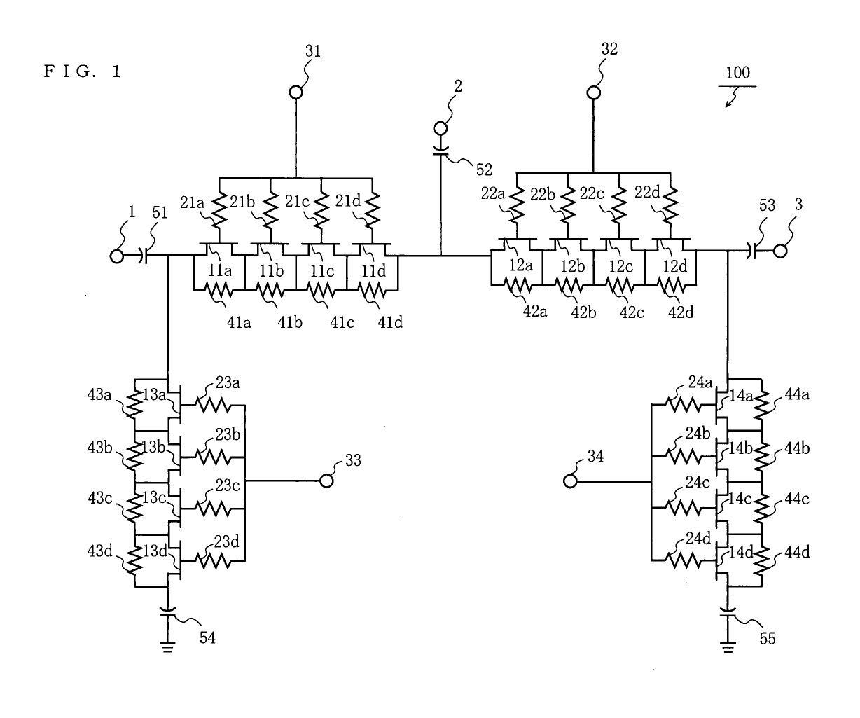

With reference to FIG. 1 through FIG. 5, a radio frequency switching circuit according to a first embodiment of the present invention will be described. A semiconductor device according to this embodiment includes the radio frequency switching circuit shown in FIG. 1 integrated on a semiconductor substrate.

FIG. 1 is a circuit diagram of a radio frequency switching circuit according to the first embodiment of the present invention. A radio frequency switching circuit 100 shown in FIG. 1 includes FETs 11a through 11d, 12a through 12d, 13a through 13d and 14a through 14d, gate bias resistors 21a through 21d, 22a through 22d, 23a through 23d and 24a through 24d, inter-stage potential fixing resistors 41a through 41d, 42a through 42d, 43a through 43d and 44a through 44d, capacitors 51 through 55, first through third input/output terminals 1 through 3, and first through fourth control terminals 31 through 34. The first through third input/output terminals 1 through 3 are provided for inputting and outputting a radio frequency signal.

As shown in FIG. 1, the FETs 11a through 11d connected in four stages are included in a first basic switching section. Similarly, the FETs 12a through 12d are included in a second basic switching section. The FETs 13a through 13d are included in a third basic switching section. The FETs 14a through 14d are included in a fourth basic switching section. The first basic switching section is provided between the first input/output terminal 1 and the second input/output terminal 2, and the second basic switching section is provided between the second input/output terminal 2 and the third input/output terminal 3. The third basic switching section is provided between the first input/output terminal 1 and the ground, and the fourth basic switching section is provided between the third input/output terminal 3 and the ground.

The first basic switching section and the second basic switching section provided between the input/output terminals are each used as a transfer circuit for transmitting a radio frequency signal. The third basic switching section and the fourth basic switching section provided between the input/output terminal and the ground are each used as a shunt circuit for allowing a leaked component of the radio frequency signal to escape to the ground. As described above, the radio frequency switching circuit 100 is structured as a combination of two transfer circuits and two shunt circuits.

Hereinafter, an operation of the radio frequency switching circuit 100 having the above structure will be described. For transmitting a signal from the first input/output terminal 1 to the second input/output terminal 2, a High voltage is applied to the first control terminal 31 and the fourth control terminal 34, and a Low voltage is applied to the second control terminal 32 and the third control terminal 33. As a result, the FETs 11a through 11d and the FETs 14a through 14d are turned ON, and the FETs 12a through 12d and the FETs 13a through 13d are turned OFF. Thus, the first input/output terminal land the second input/output terminal 2 are short circuited. Therefore, a signal can be transmitted from the first input/output terminal 1 to the second input/output terminal 2.

By contrast, for transmitting a signal from the second input/output terminal 2 to the third input/output terminal 3, a High voltage is applied to the second control terminal 32 and the third control terminal 33, and a Low voltage is applied to the first control terminal 31 and the fourth control terminal 34. As a result, the FETs 12a through 12d and the FETs 13a through 13d are turned ON, and the FETs 11a through 11d and the FETs 14a through 14d are turned OFF. Thus, the second input/output terminal 2 and the third input/output terminal 3 are short circuited. Therefore, a signal can be transmitted from the second input/output terminal 2 to the third input/output terminal 3.

The FETs included in a shunt circuit in an OFF state act as a capacitance component. For example, when the third basic switching section including the FETs 13a through 13d is in an OFF state, the voltage amplitude of a signal which is inputted to the first input/output terminal 1 is, theoretically, equally divided into four, i.e., for the FETs 13a through 13d in the third basic switching section. The inter-stage potentials between the FETs 13a through 13d are fixed to an equal level by the inter-stage potential fixing resistors 43a through 43d (in this case, the four resistors 43a through 43d have an equal resistance value as in the conventional example). Therefore, theoretically, the DC potential of the voltage between a gate electrode and a source electrode is equal among the FETs in the third basic switching section.

However, in the radio frequency switching circuit 100 also, like in the conventional radio frequency switching circuit, in the case where all the inter-stage potential fixing resistors have an equal resistance value, the FETs in a basic switching section in an OFF state result in being supplied with different voltage amplitudes and having different DC potentials. Specifically, the FET closest to the input/output terminal to which the signal is inputted results in being supplied with the largest voltage amplitude, and the FET farthest from the input/output terminal to which the signal is inputted results in supplied with the smallest voltage amplitude (see FIG. 17). In the case where the voltage amplitudes applied to the FETs in a basic switching section in an OFF state are different as described above, when the input power increases, the FET to which the largest voltage amplitude is applied is likely to be turned ON. In addition, when one FET which has been in an OFF state is turned ON, the voltage amplitude applied to the basic switching section including such an FET is divided by the remaining FETs. Therefore, the remaining FETs are also turned ON in an avalanching manner. When a basic switching section which should be in an OFF state is turned ON, a signal leak occurs. Therefore, a radio frequency switching circuit in the above-described state cannot be used for handling high power signals.

In the radio frequency switching circuit 100, the inter-stage potential fixing resistors included in each shunt circuit are arranged such that an inter-stage potential fixing resistor closer to the input/output terminal to which the signal is inputted has a smaller resistance value. Specifically, for example, the inter-stage potential fixing resistors 43a, 43b, 43c and 43d respectively have resistance values of 2.2 kΩ, 3 kΩ, 5 kΩ and 8 kΩ in consideration that a signal voltage is applied to the first input/output terminal 1 when the third basic switching section is in an OFF state (i.e., the FETs 13a through 13d are in an OFF state). The inter-stage potential fixing resistors 44a, 44b, 44c and 44d respectively have resistance values of 2.2 kΩ, 3 kΩ, 5 kΩ and 8 kΩ in consideration that a signal voltage is applied to the third input/output terminal 3 when the fourth basic switching section is in an OFF state (i.e., the FETs 14a through 14d are in an OFF state).

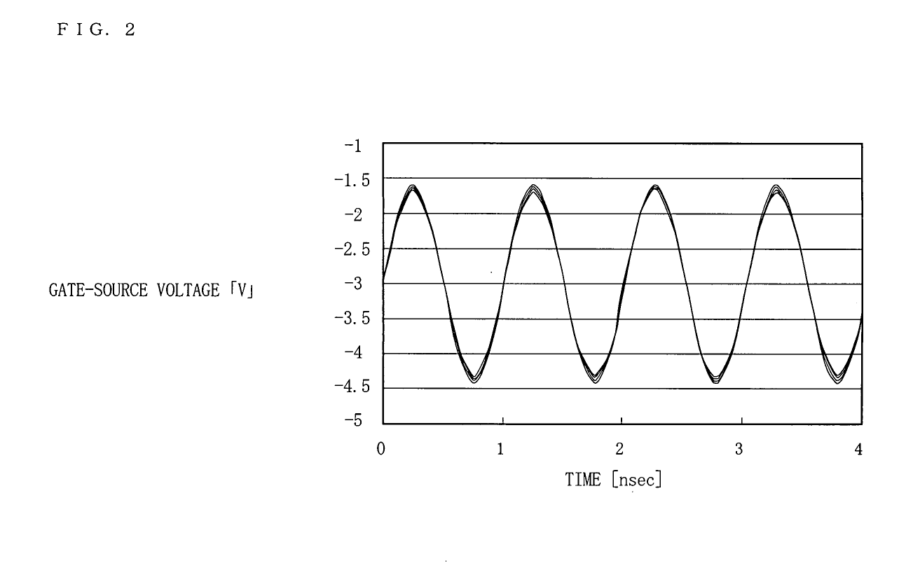

FIG. 2 shows a time-wise change in the voltage between the gate electrode and the source electrode of each FET when a signal voltage having a frequency of 1 GHz is applied to a shunt circuit having the above-described inter-stage potential fixing resistors. As shown in FIG. 2, the voltage amplitude between the gate electrode and the source electrode and the DC potential are equal among the FETs. This indicates that the signal voltage applied to the basic switching section in an OFF state is equally divided into the FETs included therein. Therefore, unlike in the conventional radio frequency switching circuit, no FET is likely to be turned ON earlier than the other FETs when a high power signal is inputted (all the FETs are simultaneously turned ON when necessary). Owing to this, the radio frequency switching circuit 100 can handle higher power signals than the conventional radio frequency switching circuit.

The inter-stage potential fixing resistors included in each transfer circuit are arranged such that an inter-stage potential fixing resistor closer to the input/output terminal to which a signal voltage is inputted when the transfer circuit is in an OFF state (hereinafter, such an input/output terminal will be referred to as an “off-time active terminal”) has a smaller resistance value. Specifically, for example, the inter-stage potential fixing resistors 42a, 42b, 42c and 42d respectively have resistance values of 2.2 kΩ, 3 kΩ, 5 kΩ and 8 kΩ in consideration that a signal voltage is applied to the second input/output terminal 2 when the second basic switching section is in an OFF state (i.e., the FETs 12a through 12d are in an OFF state). The inter-stage potential fixing resistors 41d, 41c, 41a and 41a respectively have resistance values of 2.2 kΩ, 3 kΩ, 5 kΩ and 8 kΩ in consideration that a signal voltage is applied to the second input/output terminal 2 when the first basic switching section is in an OFF state (i.e., the FETs 11a through 11d are in an OFF state).

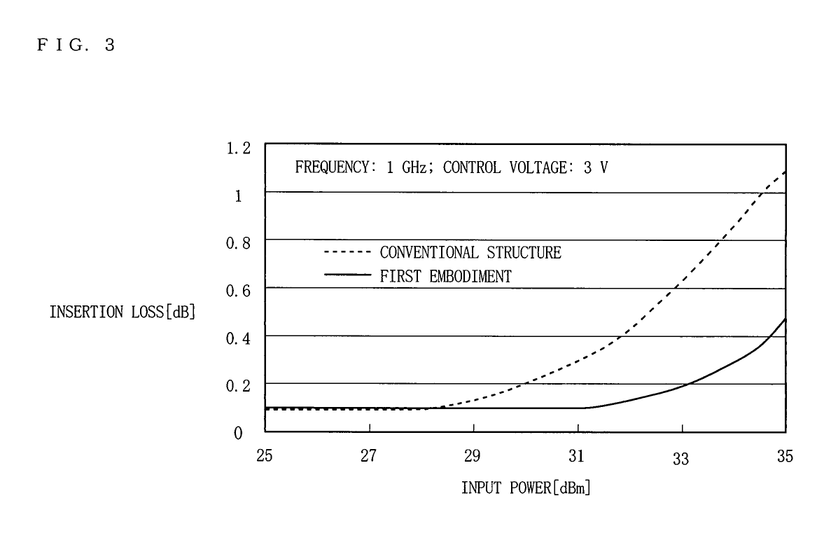

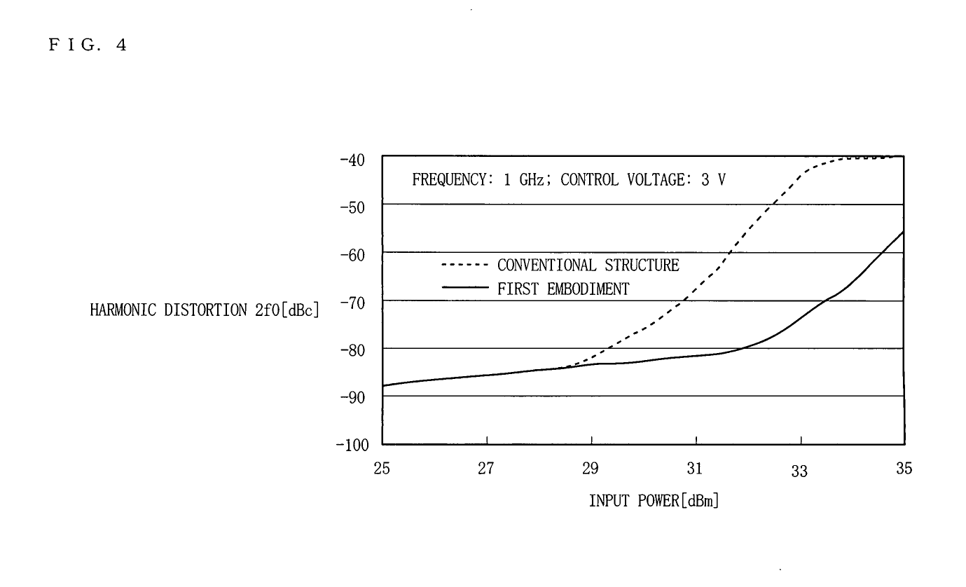

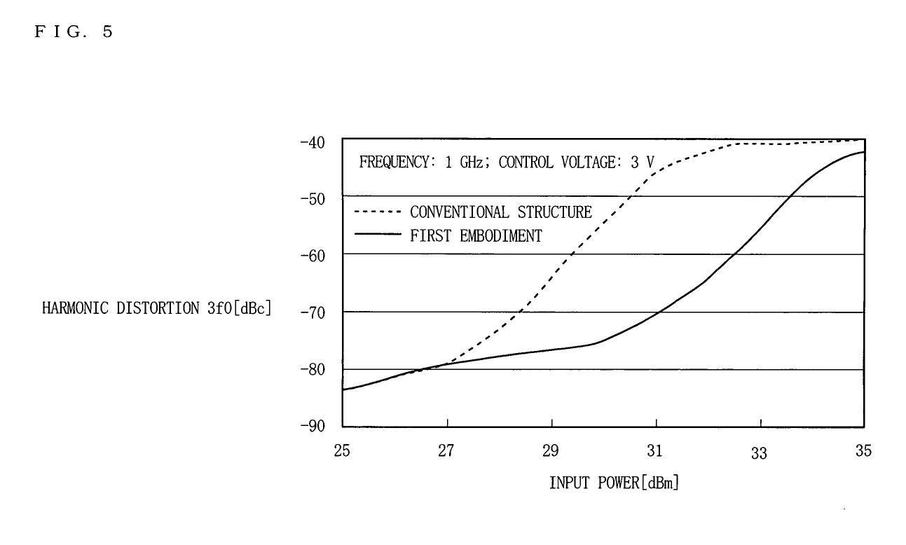

FIG. 3 shows the dependence on the input power of the insertion loss of the radio frequency switching circuit 100. FIG. 4 and FIG. 5 each show the dependence on the input power of the harmonic distortion of the radio frequency switching circuit 100. These characteristics are the same when the path from the first input/output terminal 1 to the second input/output terminal 2 is effective and when the path from the second input/output terminal 2 to the third input/output terminal 3 is effective. Accordingly, the results shown in FIG. 3 through FIG. 5 can be considered as the characteristics in either case.

In FIG. 3, the vertical axis represents the insertion loss, and the horizontal axis represents the input power. As shown in FIG. 3, in the radio frequency switching circuit 100, the insertion loss when the level of the input power is low is substantially the same as that in the conventional radio frequency switching circuit (about 0.1 dB). However, the level of the input power at which the insertion loss starts increasing is higher by about 3 dBm in the radio frequency switching circuit 100 than in the conventional radio frequency switching circuit. This indicates that the radio frequency switching circuit 100 can handle signals having a higher input level than the conventional radio frequency switching circuit.

In FIG. 4, the vertical axis represents the second-harmonic distortion, and the horizontal axis represents the input power. As shown in FIG. 4, in the radio frequency switching circuit 100, the second-harmonic distortion when the level of the input power is low is substantially the same as that in the conventional radio frequency switching circuit (about −88 dBc). However, the level of the input power at which the second-harmonic distortion starts increasing is higher by about 3 dBm in the radio frequency switching circuit 100 than in the conventional radio frequency switching circuit.

In FIG. 5, the vertical axis represents the third-harmonic distortion, and the horizontal axis represents the input power. As shown in FIG. 5, in the radio frequency switching circuit 100, the third-harmonic distortion when the level of the input power is low is substantially the same as that in the conventional radio frequency switching circuit (about −83 dBc). However, the level of the input power at which the third-harmonic distortion starts increasing is higher by about 3 dBm in the radio frequency switching circuit 100 than in the conventional radio frequency switching circuit.

The resistance values of the inter-stage potential fixing resistors 41a through 41d, 42a through 42d, 43a through 43a and 44a through 44d of the radio frequency switching circuit 100 described above are merely exemplary, and the inter-stage potential fixing resistors may have other resistance values.

In general, in the case where a basic switching section is a shunt circuit including n number of FETs (n is an integer of 2 or greater) which are connected in series, it is sufficient that Rds(1) is smaller than each of Rds(2) through Rds(n) where Rds(i) is the resistance value of the resistor connected between the drain electrode and the source electrode of the i'th FET (i is an integer of 1 or greater and n or smaller) from the input/output terminal. More preferably, the resistance values may have the relationship represented by the following expression (11). Still more preferably, the resistance values may have the relationship represented by the following expression (12).
Rds(1)<Rds(2)≦ . . . ≦Rds(n-1)≦Rds(n) (11)
Rds(1)<Rds(2)< . . . <Rds(n-1)<Rds(n) (12)

In the case where a basic switching section is a transfer circuit including n number of FETs (n is an integer of 2 or greater) which are connected in series, it is sufficient that Rds(1) is smaller than each of Rds(2) through Rds(n) where Rds(i) is the resistance value of the resistor connected between the drain electrode and the source electrode of the i'th FET (i is an integer of 1 or greater and n or smaller) from the off-time active terminal. More preferably, the resistance values may have the relationship represented by the following expression (21). Still more preferably, the resistance values may have the relationship represented by the following expression (22).
Rds(1)<Rds(2)≦ . . . ≦Rds(n-1)≦Rds(n) (21)
Rds(1)<Rds(2)< . . . <Rds(n-1)<Rds(n) (22)

As described above, a radio frequency switching circuit capable of handling higher power signals than the conventional radio frequency switching circuit can be provided by using resistors having different resistance values as inter-stage potential fixing resistors connected between the drain electrodes and the source electrodes of FETs connected in a plurality of stages.

### Second Embodiment

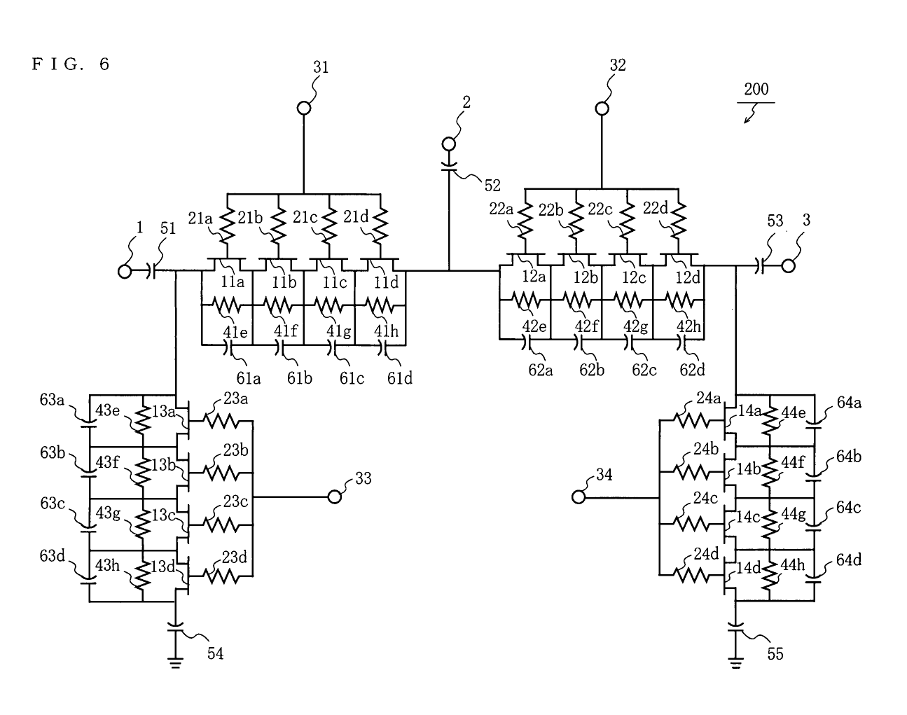

With reference to FIG. 6 through FIG. 9, a radio frequency switching circuit according to a second embodiment of the present invention will be described. A semiconductor device according to this embodiment includes the radio frequency switching circuit shown in FIG. 6 integrated on a semiconductor substrate.

FIG. 6 is a circuit diagram of a radio frequency switching circuit according to the second embodiment of the present invention. A radio frequency switching circuit 200 shown in FIG. 6 includes FETs 11a through 11d, 12a through 12d, 13a through 13d and 14a through 14d, gate bias resistors 21a through 21d, 22a through 22d, 23a through 23d and 24a through 24d, inter-stage potential fixing resistors 41e through 41h, 42e through 42h, 43e through 43h and 44e through 44h, capacitors 51 through 55, 61a through 61d, 62a through 62d, 63a through 63d and 64a through 64d, first through third input/output terminals 1 through 3, and first through fourth control terminals 31 through 34. The first through third input/output terminals 1 through 3 are provided for inputting and outputting a radio frequency signal. Among the elements in this embodiment, elements identical to those of the first embodiment bear the identical reference numerals thereto, and descriptions thereof will be omitted.

Like in the radio frequency switching circuit 100 in the first embodiment, as shown in FIG. 6, the FETs 11a through 11d connected in four stages are included in a first basic switching section. Similarly, the FETs 12a through 12d are included in a second basic switching section. The FETs 13a through 13d are included in a third basic switching section. The FETs 14a through 14d are included in a fourth basic switching section. The first basic switching section is provided between the first input/output terminal 1 and the second input/output terminal 2, and the second basic switching section is provided between the second input/output terminal 2 and the third input/output terminal 3. The third basic switching section is provided between the first input/output terminal 1 and the ground, and the fourth basic switching section is provided between the third input/output terminal 3 and the ground.

In the radio frequency switching circuit 200, like in the radio frequency switching circuit 100, the first basic switching section and the second basic switching section each act as a transfer circuit. The third basic switching section and the fourth basic switching section each act as a shunt circuit. The radio frequency switching circuit 200 is structured as a combination of two transfer circuits and two shunt circuits. The operation of the radio frequency switching circuit 200 for transmitting a signal is substantially the same as that of the radio frequency switching circuit 100 and will not be repeated here.

In the radio frequency switching circuit 200 also, like in the conventional radio frequency switching circuit, in the case where all the inter-stage potential fixing resistors have an equal resistance value, the FETs in a basic switching section in an OFF state result in being supplied with different voltage amplitudes and having different DC potentials. In the case where the voltage amplitudes applied to the FETs in a basic switching section in an OFF state are different as described above, when the input power increases, the FET to which the largest voltage amplitude is applied to is likely to be turned ON. When a basic switching section which should be in an OFF state is turned ON, a signal leak occurs. Therefore, a radio frequency switching circuit in the above-described state cannot be used for handling high power signals.

In the radio frequency switching circuit 200, a capacitor is connected between a drain electrode and a source electrode of each FET included in each shunt circuit. The capacitors are arranged such that a capacitor closer to the input/output terminal to which the signal is inputted has a larger capacitance value. Specifically, for example, the capacitors.63a, 63b, 63c and 63d respectively have capacitance values of 0.98 pF, 0.95 pF, 0.92 pF and 0.90 pF in consideration that a signal voltage is applied to the first input/output terminal 1 when the third basic switching section is in an OFF state (i.e., the FETs 13a through 13d are in an OFF state). The capacitors 64a, 64b, 64c and 64d respectively have capacitance values of 0.98 pF, 0.95 pF, 0.92 pF and 0.90 pF in consideration that a signal voltage is applied to the third input/output terminal 3 when the fourth basic switching section is in an OFF state (i.e., the FETs 14a through 14d are in an OFF state).

When a signal voltage is applied to a shunt circuit having the capacitors as described above, the voltage amplitude between the gate electrode and the source electrode and the DC potential are equal among the FETs (not shown). Owing to this, like the radio frequency switching circuit 100 in the first embodiment, the radio frequency switching circuit 200 can handle higher power signals than the conventional radio frequency switching circuit.

The capacitors included in each transfer circuit are arranged such that a capacitor closer to the off-time active terminal has a larger capacitance value. Specifically, for example, the capacitors 62a, 62b, 62c and 62d respectively have capacitance values of 0.98 pF, 0.95 pF, 0.92 pF and 0.90 pF in consideration that a signal voltage is applied to the second input/output terminal 2 when the second basic switching section is in an OFF state (i.e., the FETs 12a through 12d are in an OFF state). The capacitors 61d, 61c, 61b and 61a respectively have capacitance values of 0.98 pF, 0.95 pF, 0.92 pF and 0.90 pF in consideration that a signal voltage is applied to the second input/output terminal 2 when the first basic switching section is in an OFF state (i.e., the FETs 11a through 11d are in an OFF state).

In the radio frequency switching circuit 200, the inter-stage potential fixing resistors 41e through 41h, 42e through 42h, 43e through 43h and 44e through 44h have an equal resistance value.

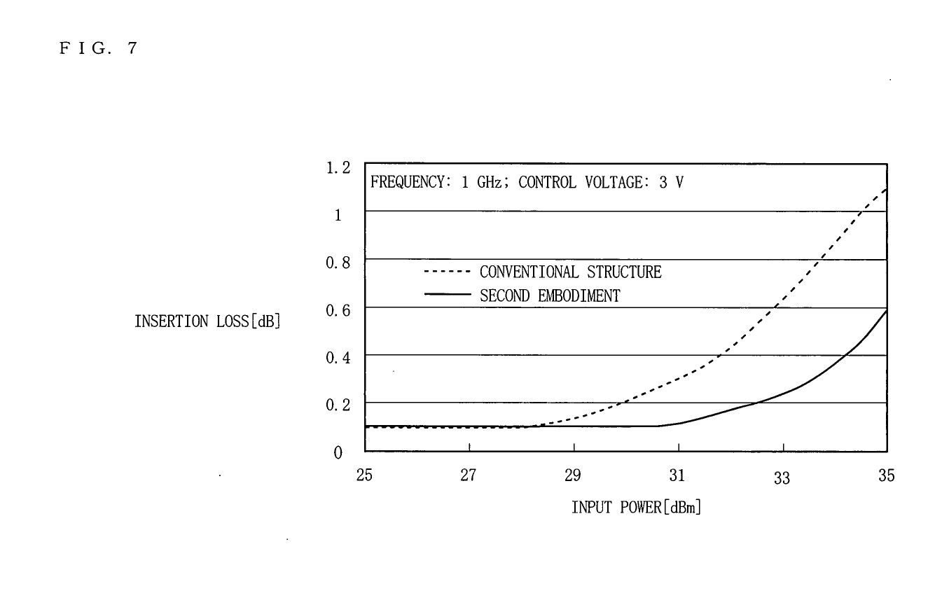

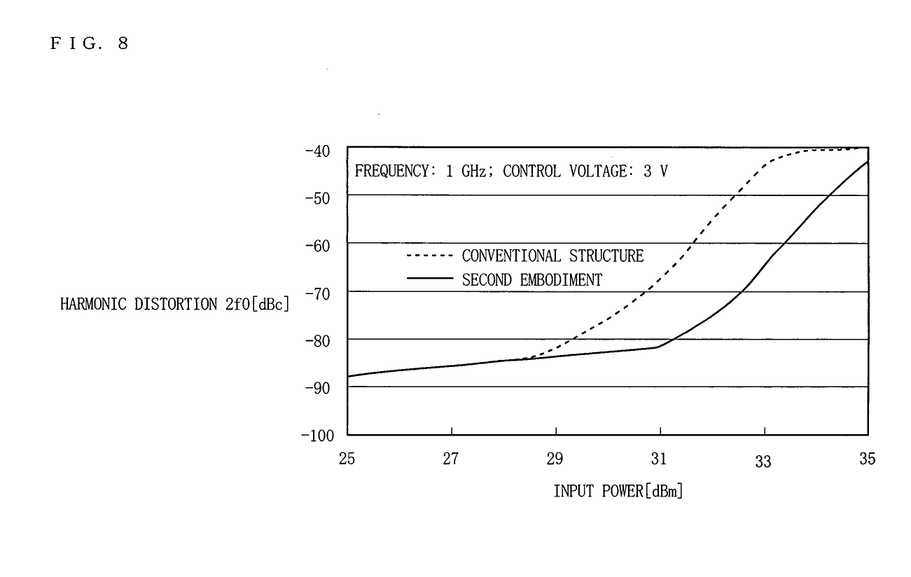

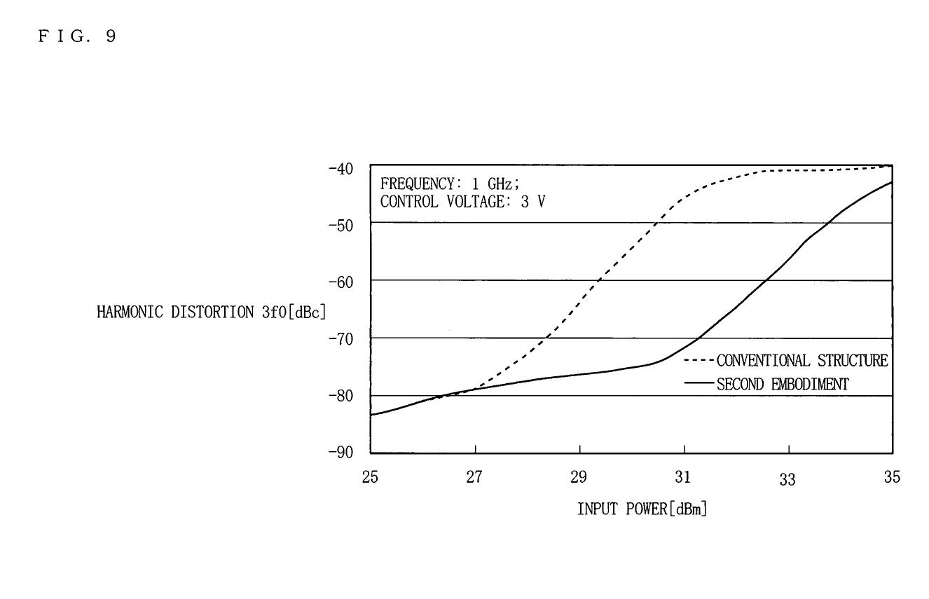

FIG. 7 shows the dependence on the input power of the insertion loss of the radio frequency switching circuit 200. FIG. 8 and FIG. 9 each show the dependence on the input power of the harmonic distortion of the radio frequency switching circuit 200. These characteristics are the same when the path from the first input/output terminal 1 to the second input/output terminal 2 is effective and when the path from the second input/output terminal 2 to the third input/output terminal 3 is effective. Accordingly, the results shown in FIG. 7 through FIG. 9 can be considered as the characteristics in either case.

In FIG. 7, the vertical axis represents the insertion loss, and the horizontal axis represents the input power. As shown in FIG. 7, in the radio frequency switching circuit 200, the insertion loss when the level of the input power is low is substantially the same as that in the conventional radio frequency switching circuit (about 0.1 dB). However, the level of the input power at which the insertion loss starts increasing is higher by about 2.5 dBm in the radio frequency switching circuit 200 than in the conventional radio frequency switching circuit. This indicates that the radio frequency switching circuit 200 can handle signals having a higher input level than the conventional radio frequency switching circuit.

In FIG. 8, the vertical axis represents the second-harmonic distortion, and the horizontal axis represents the input power. As shown in FIG. 8, in the radio frequency switching circuit 200, the second-harmonic distortion when the level of the input power is low is substantially the same as that in the conventional radio frequency switching circuit (about −88 dBc). However, the level of the input power at which the second-harmonic distortion starts increasing is higher by about 2.5 dBm in the radio frequency switching circuit 200 than in the conventional radio frequency switching circuit.

In FIG. 9, the vertical axis represents the third-harmonic distortion, and the horizontal axis represents the input power. As shown in FIG. 9, in the radio frequency switching circuit 200, the third-harmonic distortion when the level of the input power is low is substantially the same as that in the conventional radio frequency switching circuit (about −83 dBc) However, the level of the input power at which the third-harmonic distortion starts increasing is higher by about 3 dBm in the radio frequency switching circuit 200 than in the conventional radio frequency switching circuit.

The capacitance values of the capacitors 61a through 61d, 62a through 62d, 63a through 63a and 64a through 64d of the radio frequency switching circuit 200 described above are merely exemplary, and the capacitors may have other capacitance values.

In general, in the case where a basic switching section is a shunt circuit including n number of FETs (n is an integer of 2 or greater) which are connected in series, it is sufficient that Cds(1) is larger than each of Cds(2) through Cds(n) where Cds(i) is the capacitance value of the capacitor connected between the drain electrode and the source electrode of the i'th FET (i is an integer of 1 or greater and n or smaller) from the input/output terminal. More preferably, the capacitance values may have the relationship represented by the following expression (31). Still more preferably, the capacitance values may have the relationship represented by the following expression (32).
Cds(1)>Cds(2)≧ . . . ≧Cds(n-1)≧Cds(n) (31)
Cds(1)>Cds(2)> . . . >Cds(n-1)>Cds(n) (32)

In the case where a basic switching section is a transfer circuit including n number of FETs (n is an integer of 2 or greater) which are connected in series, it is sufficient that Cds(1) is larger than each of Cds(2) through Cds(n) where Cds(i) is the capacitance value of the capacitor connected between the drain electrode and the source electrode of the i'th FET (i is an integer of 1 or greater and n or smaller) from the off-time active terminal. More preferably, the capacitance values may have the relationship represented by the following expression (41). Still more preferably, the capacitance values may have the relationship represented by the following expression (42).
Cds(1)>Cds(2)≧ . . . ≧Cds(n-1)≧Cds(n) (41)
Cds(1)>Cds(2)> . . . >Cds(n-1)>Cds(n) (42)

As described above, a radio frequency switching circuit capable of handling higher power signals than the conventional radio frequency switching circuit can be provided by connecting capacitors having different capacitance values between the drain electrodes and the source electrodes of FETs connected in a plurality of stages.

In the radio frequency switching circuit 200 in this embodiment, the inter-stage potential fixing resistors 41e through 41h, 42e through 42h, 43e through 43h and 44e through 44h have an equal resistance value. Alternatively, these inter-stage potential fixing resistors may have different resistance values like in the radio frequency switching circuit 100 in the first embodiment.

### Third Embodiment

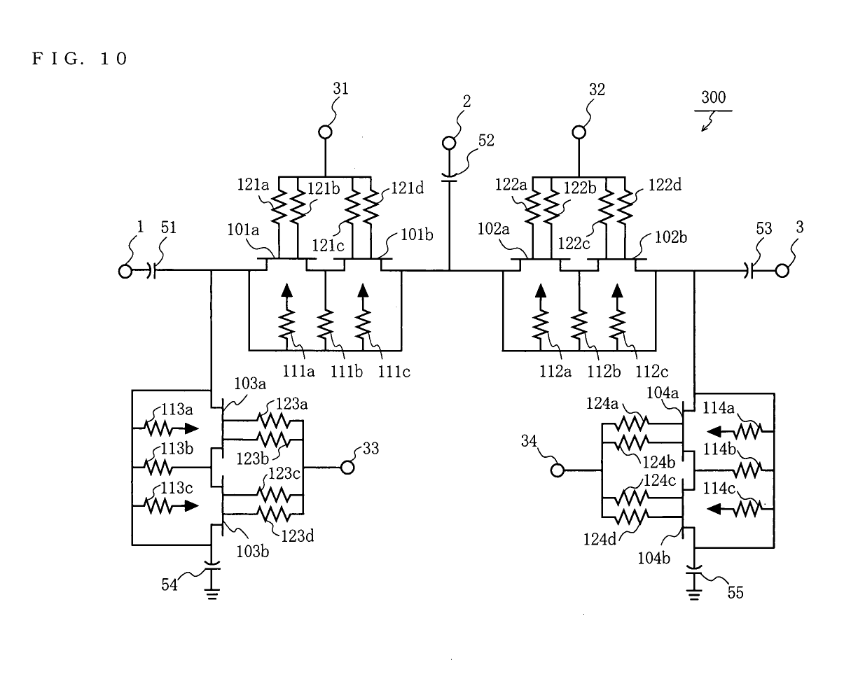

With reference to FIG. 10 through FIG. 13, a radio frequency switching circuit according to a third embodiment of the present invention will be described. In the radio frequency switching circuit according to this embodiment, the FETs connected in a plurality of stages in the first embodiment are replaced with multi-gate FETs (dual-gate FETs in this example). A semiconductor device according to this embodiment includes the radio frequency switching circuit shown in FIG. 10 integrated on a semiconductor substrate.

FIG. 10 is a circuit diagram of a radio frequency switching circuit according to the third embodiment of the present invention. A radio frequency switching circuit 300 shown in FIG. 10 includes multi-gate FETs 101a, 101b, 102a, 102b, 103a, 103b, 104a and 104b, gate bias resistors 121a through 121d, 122a through 122d, 123a through 123d and 124a through 124d, inter-stage potential fixing resistors 111a through 111c, 112a through 112c, 113a through 113c and 114a through 114c, capacitors 51 through 55, first through third input/output terminals 1 through 3, and first through fourth control terminals 31 through 34. Among the elements in this embodiment, elements identical to those of the first embodiment bear the identical reference numerals thereto, and descriptions thereof will be omitted.

As shown in FIG. 10, the multi-gate FETs 101a and 101b connected in two stages are included in a first basic switching section. Similarly, the multi-gate FETs 102a and 102b are included in a second basic switching section. The multi-gate FETs 103a and 103b are included in a third basic switching section. The multi-gate FETs 104a and 104b are included in a fourth basic switching section. The first basic switching section is provided between the first input/output terminal 1 and the second input/output terminal 2, and the second basic switching section is provided between the second input/output terminal 2 and the third input/output terminal 3. The third basic switching section is provided between the first input/output terminal 1 and the ground, and the fourth basic switching section is provided between the third input/output terminal 3 and the ground.

Like in the radio frequency switching circuit 100 in the first embodiment, the first and second basic switching sections each act as a transfer circuit, the third and fourth basic switching sections each act as a shunt circuit, and the radio frequency switching circuit 300 is structured as a combination of two transfer circuits and two shunt circuits.

The multi-gate FETs 101a, 101b, 102a, 102b, 103a, 103b, 104a and 104b each have two gate electrodes. The first basic switching section includes the first gate bias resistor 121a, the second gate bias resistor 121b, the third gate bias resistor 121c, and the fourth gate bias resistor 121d from the side of the first input/output terminal 1. The second basic switching section includes the first gate bias resistor 122a, the second gate bias resistor 122b, the third gate bias resistor 122c, and the fourth gate bias resistor 122d from the side of the second input/output terminal 2. The third basic switching section includes the first gate bias resistor 123a, the second gate bias resistor 123b, the third gate bias resistor 123c, and the fourth gate bias resistor 123d from the side of the first input/output terminal 1. The fourth basic switching section includes the first gate bias resistor 124a, the second gate bias resistor 124b, the third gate bias resistor 124c, and the fourth gate bias resistor 124d from the side of the third input/output terminal 3.

The first basic switching section further includes the inter-stage potential fixing resistor 111a between a source electrode and an inter-gate electrode mesa of the multi-gate FET 101a, the inter-stage potential fixing resistor 111b between the multi-gate FET 101a and the multi-gate FET 101b, and the inter-stage potential fixing resistor 111c between a source electrode and an inter-gate electrode mesa of the multi-gate FET 101b. The second basic switching section further includes the inter-stage potential fixing resistor 112a between a source electrode and an inter-gate electrode mesa of the multi-gate FET 102a, the inter-stage potential fixing resistor 112b between the multi-gate FET 102a and the multi-gate FET 102b, and the inter-stage potential fixing resistor 112c between a source electrode and an inter-gate electrode mesa of the multi-gate FET 102b. The third basic switching section further includes the inter-stage potential fixing resistor 113a between a source electrode and an inter-gate electrode mesa of the multi-gate FET 103a, the inter-stage potential fixing resistor 113b between the multi-gate FET 103a and the multi-gate FET 103b, and the inter-stage potential fixing resistor 113c between a source electrode and an inter-gate electrode mesa of the multi-gate FET 103b. The fourth basic switching section further includes the inter-stage potential fixing resistor 114a between a source electrode and an inter-gate electrode mesa of the multi-gate FET 104a, the inter-stage potential fixing resistor 114b between the multi-gate FET 104a and the multi-gate FET 104b, and the inter-stage potential fixing resistor 114c between a source electrode and an inter-gate electrode mesa of the multi-gate FET 104b.

Hereinafter, an operation of the radio frequency switching circuit 300 having the above structure will be described. For transmitting a signal from the first input/output terminal 1 to the second input/output terminal 2, a High voltage is applied to the first control terminal 31 and the fourth control terminal 34, and a Low voltage is applied to the second control terminal 32 and the third control terminal 33. As a result, the multi-gate FETs 101a, 101b, 104a and 104b are turned ON, and the multi-gate FETs 102a, 102b, 103a and 103b are turned OFF. Thus, the first input/output terminal 1 and the second input/output terminal 2 are short circuited. Therefore, a signal can be transmitted from the first input/output terminal 1 to the second input/output terminal 2.

By contrast, for transmitting a signal from the second input/output terminal 2 to the third input/output terminal 3, a High voltage is applied to the second control terminal 32 and the third control terminal 33, and a Low voltage is applied to the first control terminal 31 and the fourth control terminal 34. As a result, the multi-gate FETs 102a, 102b, 103a and 103b are turned ON, and the multi-gate FETs 101a, 101b, 104a and 104b are turned OFF. Thus, the second input/output terminal 2 and the third input/output terminal 3 are short circuited. Therefore, a signal can be transmitted from the second input/output terminal 2 to the third input/output terminal 3.

In the radio frequency switching circuit 300 also, like in the radio frequency switching circuit 100 in the first embodiment, the multi-gate FETs included in a shunt circuit in an OFF state act as a capacitance component. For example, when the third basic switching section including the multi-gate FETs 103a and 103b is in an OFF state, the voltage amplitude of a signal which is inputted to the first input/output terminal 1 is, theoretically, equally divided into two, i.e., for the FETs 103a and 103b in the third basic switching section. The inter-stage potential between the multi-gate FETs 103a and 103b, and the potential of the inter-gate electrode mesa of each of the multi-gate FETs 103a and 103b, are fixed to an equal level by the inter-stage potential fixing resistors 113a through 113c (in this case, the three resistors 113a through 113c have an equal resistance value). Therefore, theoretically, the DC potential of the voltage between the gate electrode and the source electrode is equal among the FETs in the third basic switching section.

However, in the radio frequency switching circuit 300 also, like in the conventional radio frequency switching circuit, in the case where all the inter-stage potential fixing resistors have an equal resistance value, the multi-gate FETs in a basic switching section in an OFF state result in being supplied with different voltage amplitudes and having different DC potentials. Specifically, the voltage amplitude applied between the source electrode and the inter-gate electrode mesa of the multi-gate FET closest to the input/output terminal to which the signal is inputted results in being largest, and the voltage amplitude applied between the inter-gate electrode mesa and the drain electrode of the multi-gate FET farthest from the input/output terminal to which the signal is inputted results in being smallest. In the case where the voltage amplitudes applied to the multi-gate FETs in a basic switching section in an OFF state are different as described above, when the input power increases, an FET portion, provided by the source electrode and the inter-gate electrode mesa of the multi-gate FET, to which the largest voltage amplitude is applied is likely to be turned ON. In addition, when one such FET portion which has been in an OFF state is turned ON, the voltage amplitude applied to the basic switching section including such an FET portion is divided by the remaining FET portions. Therefore, the remaining FET portions are also turned ON in an avalanching manner. When a basic switching section which should be in an OFF state is turned ON, a signal leak occurs. Therefore, a radio frequency switching circuit in the above-described state cannot be used for handling high power signals.

In the radio frequency switching circuit 300, the inter-stage potential fixing resistors included in each shunt circuit are arranged such that an inter-stage potential fixing resistor closer to the input/output terminal to which the signal is inputted has a smaller resistance value. Specifically, for example, the inter-stage potential fixing resistors 113a, 113b and 113c respectively have resistance values of 3 kΩ, 5 kΩ and 8 kΩ in consideration that a signal voltage is applied to the first input/output terminal 1 when the third basic switching section is in an OFF state (i.e., the multi-gate FETs 103a and 103b are in an OFF state). The inter-stage potential fixing resistors 114a, 114b and 114c respectively have resistance values of 3 kΩ, 5 kΩ and 8 kΩ in consideration that a signal voltage is applied to the third input/output terminal 3 when the fourth basic switching section is in an OFF state (i.e., the multi-gate FETs 104a and 104b are in an OFF state).

When a signal voltage is applied to a shunt circuit having the inter-stage potential fixing resistors as described above, the voltage amplitude between the gate electrode and the source electrode and the DC potential are equal among the multi-gate FETs (not shown). Owing to this, like the radio frequency switching circuit 100 in the first embodiment, the radio frequency switching circuit 300 can handle higher power signals than the conventional radio frequency switching circuit.

The inter-stage potential fixing resistors included in each transfer circuit are arranged such that an inter-stage potential fixing resistor closer to the input/output terminal to which a signal voltage is inputted when the transfer circuit is in an OFF state (hereinafter, such an input/output terminal will be referred to as an “off-time active terminal”) has a smaller resistance value. Specifically, for example, the inter-stage potential fixing resistors 112a, 112b and 112c respectively have resistance values of 3 kΩ, 5 kΩ and 8 kΩ in consideration that a signal voltage is applied to the second input/output terminal 2 when the second basic switching section is in an OFF state (i.e., the multi-gate FETs 102a and 102b are in an OFF state). The inter-stage potential fixing resistors 111c, 111b and 111a respectively have resistance values of 3 kΩ, 5 kΩ and 8 kΩ in consideration that a signal voltage is applied to the second input/output terminal 2 when the first basic switching section is in an OFF state (i.e., the multi-gate FETs 101a and 101b are in an OFF state).

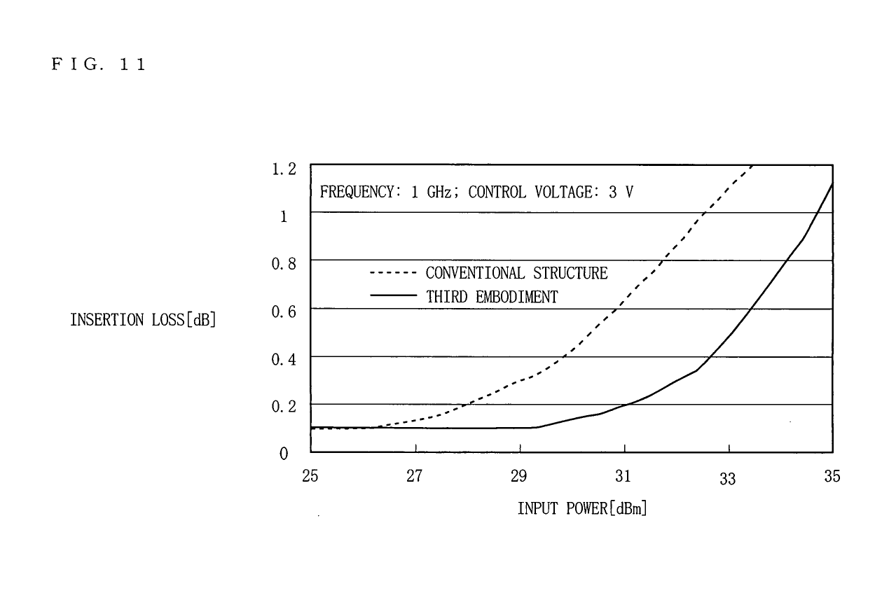

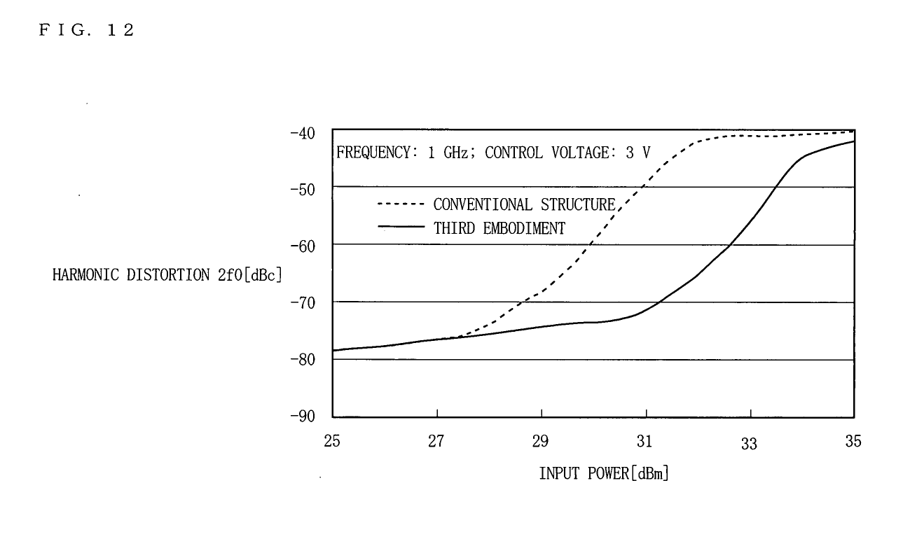

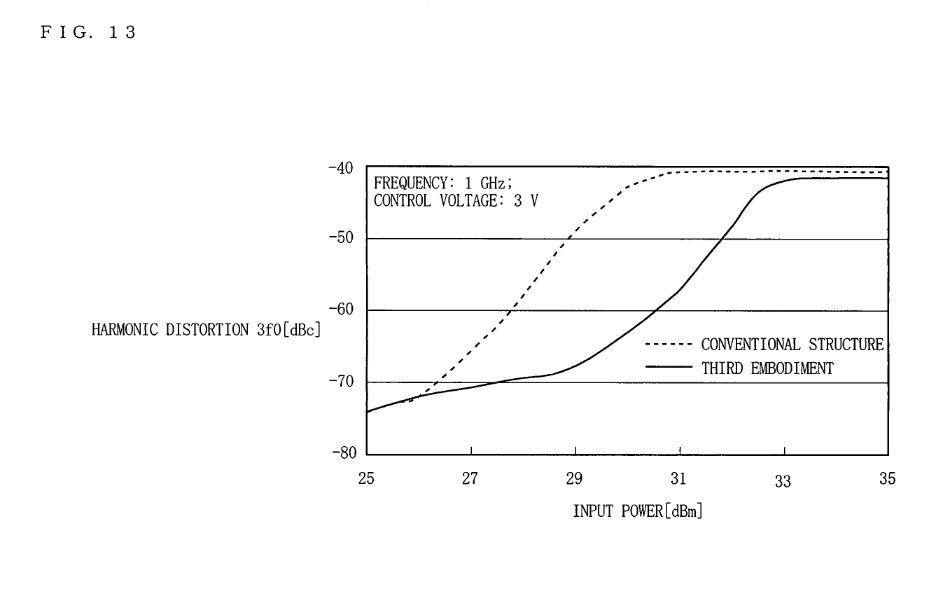

FIG. 11 shows the dependence on the input power of the insertion loss of the radio frequency switching circuit 300 in this embodiment. FIG. 12 and FIG. 13 each show the dependence on the input power of the harmonic distortion of the radio frequency switching circuit 300. These characteristics are the same when the path from the first input/output terminal 1 to the second input/output terminal 2 is effective and when the path from the second input/output terminal 2 to the third input/output terminal 3 is effective. Accordingly, the results shown in FIG. 11 through FIG. 13 can be considered as the characteristics in either case.

In FIG. 11, the vertical axis represents the insertion loss, and the horizontal axis represents the input power. As shown in FIG. 11, in the radio frequency switching circuit 300, the insertion loss when the level of the input power is low is substantially the same as that in the conventional radio frequency switching circuit (about 0.1 dB). However, the level of the input power at which the insertion loss starts increasing is higher by about 3 dBm in the radio frequency switching circuit 300 than in the conventional radio frequency switching circuit. This indicates that the radio frequency switching circuit 300 can handle signals having a higher input level than the conventional radio frequency switching circuit.

In FIG. 12, the vertical axis represents the second-harmonic distortion, and the horizontal axis represents the input power. As shown in FIG. 12, in the radio frequency switching circuit 300, the second-harmonic distortion when the level of the input power is low is substantially the same as that in the conventional radio frequency switching circuit (about −78 dBc). However, the level of the input power at which the second-harmonic distortion starts increasing is higher by about 3 dBm in the radio frequency switching circuit 300 than in the conventional radio frequency switching circuit.

In FIG. 13, the vertical axis represents the third-harmonic distortion, and the horizontal axis represents the input power. As shown in FIG. 13, in the radio frequency switching circuit 300, the third-harmonic distortion when the level of the input power is low is substantially the same as that in the conventional radio frequency switching circuit (about −74 dBc). However, the level of the input power at which the third-harmonic distortion starts increasing is higher by about 3 dBm in the radio frequency switching circuit 300 than in the conventional radio frequency switching circuit.

The resistance values of the inter-stage potential fixing resistors 111a through 111c, 112a through 112c, 113a through 113c and 114a through 114c of the radio frequency switching circuit 300 described above are merely exemplary, and the inter-stage potential fixing resistors may have other resistance values.

In general, in the case where a basic switching section is a shunt circuit including n number of multi-gate FETs (n is an integer of 2 or greater) which are connected in series, it is sufficient that Rms(1) is smaller than each of Rms(2) through Rms(n) where Rms(i) is the resistance value of the resistor connected between the source electrode and the inter-gate electrode mesa of the i'th multi-gate FET (i is an integer of 1 or greater and n or smaller) from the input/output terminal. More preferably, the resistance values may have the relationship represented by the following expression (51). Still more preferably, the resistance values may have the relationship represented by the following expression (52).
Rms(1)<Rms(2)≦ . . . ≦Rms(n-1)≦Rms(n) (51)
Rms(1)<Rms(2)< . . . <Rms(n-1)<Rms(n) (52)

In the case where a basic switching section is a transfer circuit including n number of multi-gate FETs (n is an integer of 2 or greater) which are connected in series, it is sufficient that Rms(1) is smaller than each of Rms(2) through Rms(n) where Rms(i) is the resistance value of the resistor connected between the source electrode and the inter-gate electrode mesa of the i'th multi-gate FET (i is an integer of 1 or greater and n or smaller) from the off-time active terminal. More preferably, the resistance values may have the relationship represented by the following expression (61). Still more preferably, the resistance values may have the relationship represented by the following expression (62).
Rms(1)<Rms(2)≦ . . . ≦Rms(n-1)≦Rms(n) (61)
Rms(1)<Rms(2)< . . . <Rms(n-1)<Rms(n) (62)

In the radio frequency switching circuit 300 in this embodiment also, capacitors having different capacitance values as in the second embodiment may be connected between the source electrodes and the inter-gate electrode mesas of the multi-gate FETs instead of the inter-stage potential fixing resistors.

In more detail, in the case where a basic switching section is a shunt circuit including n number of multi-gate FETs (n is an integer of 2 or greater) which are connected in series, it is sufficient that Cms(1) is larger than each of Cms(2) through Cms(n) where Cms(i) is the capacitance value of the capacitor connected between the source electrode and the inter-gate electrode mesa of the i'th multi-gate FET (i is an integer of 1 or greater and n or smaller) from the input/output terminal. More preferably, the capacitance values may have the relationship represented by the following expression (71). Still more preferably, the capacitance values may have the relationship represented by the following expression (72).
Cms(1)>Cms(2)≧ . . . ≧Cms(n-1)≧Cms(n) (71)
Cms(1)>Cms(2)> . . . >Cms(n-1)>Cms(n) (72)

In the case where a basic switching section is a transfer circuit including n number of multi-gate FETs (n is an integer of 2 or greater) which are connected in series, it is sufficient that Cms(1) is larger than each of Cms(2) through Cms(n) where Cms(i) is the capacitance value of the capacitor connected between the source electrode and the inter-gate electrode mesa of the i'th multi-gate FET (i is an integer of 1 or greater and n or smaller) from the off-time active terminal. More preferably, the capacitance values may have the relationship represented by the following expression (81). Still more preferably, the capacitance values may have the relationship represented by the following expression (82).
Cms(1)>Cms(2)≧ . . . ≧Cms(n-1)>Cms(n) (81)
Cms(1)>Cms(2)> . . . >Cms(n-1)>Cms(n) (82)

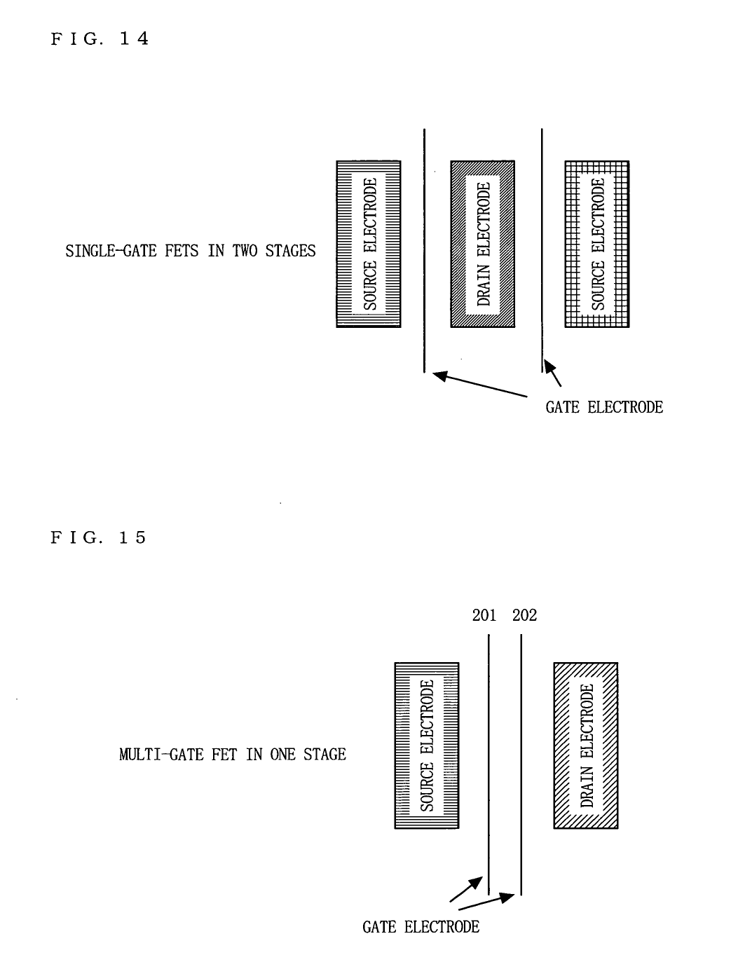

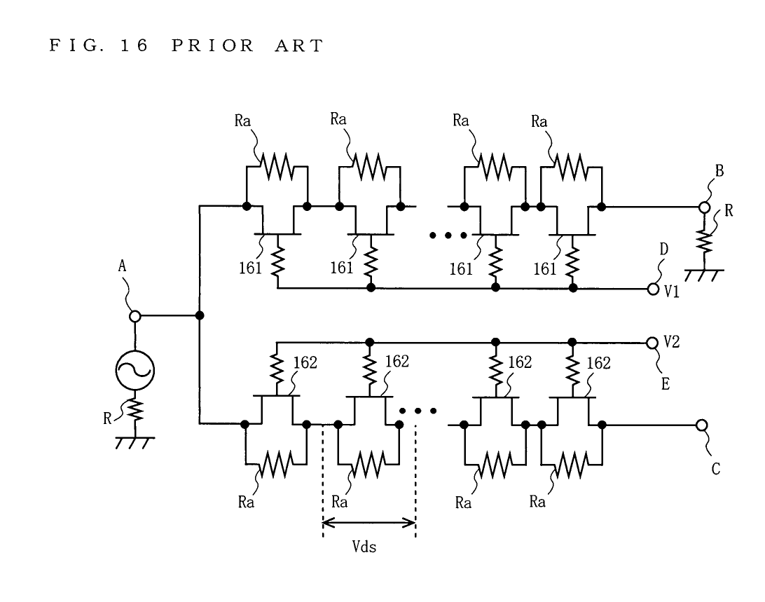

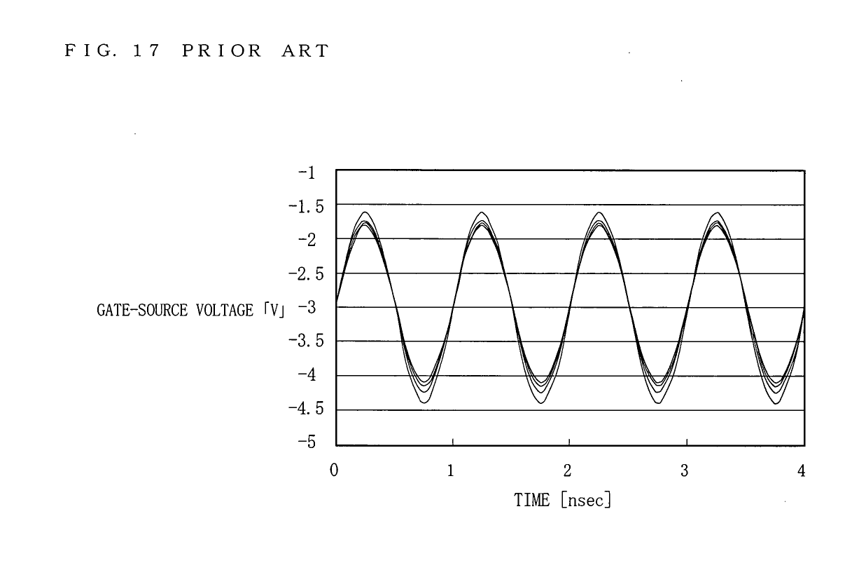

FIG. 14 shows a structure of single-gate FETs connected in two stages. In the FETs connected in two stages as shown in FIG. 14, a gate electrode, to which a control voltage for controlling the FETs to be ON or OFF is to be applied, is inserted between source electrodes and a drain electrode through which a signal flows. FIG. 15 shows a structure of a multi-gate FET (dual-gate FET in this example). In the multi-gate FET shown in FIG. 15, two gate electrodes 201 and 202 are inserted between a source electrode and a drain electrode through which a signal flows. In this case, a mesa between the first gate electrode 201 and the second gate electrode 202 connect an FET portion including the first gate electrode 201 and an FET portion including the second gate electrode 202 to each other. In terms of characteristics, one such multi-gate FET corresponds to two single-gate FETs.

Comparing FIG. 14 and FIG. 15, it is understood that the multi-gate FET shown in FIG. 15 has the same characteristics as those of the two single-gate FETs connected in series but has a smaller size than the two single-gate FETs. In actuality, an SPDT (Single Pole Double Throw) radio frequency switching circuit using multi-gate FETs can reduce the chip size by 30% as compared to a radio frequency switching circuit using single-gate FETs.

As described above, a radio frequency switching circuit capable of handling higher power signals than the conventional radio frequency switching circuit can be provided by connecting resistors having different resistance values, or by connecting capacitors having different capacitance values, between the source electrodes and the inter-gate electrode mesas of multi-gate FETs connected in a plurality of stages. By using a multi-gate FET, the chip size can be reduced as compared to using single-gate FETs.

In the first through third embodiments, the same type of radio frequency switching circuits are combined to optionally switch the flow of a radio frequency signal between a plurality of input/output terminals. Alternatively, different types of radio frequency switching circuits may be combined to optionally switch the flow of a radio frequency signal between a plurality of input/output terminals.

A radio frequency switching circuit according to the present invention has improved input/output power characteristics over the conventional radio frequency switching circuit, and therefore is useful for various types of radio frequency switching circuits or the like for handling high power signals.

While the invention has been described in detail, the foregoing description is in all aspects illustrative and not restrictive. It is understood that numerous other modifications and variations can be devised without departing from the scope of the invention.

1. A radio frequency switching circuit for controlling a flow of a radio frequency signal, comprising:
a basic switching section including a plurality of field effect transistors connected in series and provided between an input/output terminal for inputting and outputting the radio frequency signal and the ground; and
a plurality of resistor elements each having one terminal connected to a drain electrode of a corresponding field effect transistor among the plurality of field effect transistors and having the other terminal connected to a source electrode of the corresponding field effect transistor;
wherein a resistor among the plurality of resistors which is connected between the drain electrode and the source electrode of a field effect transistor, among the plurality of field effect transistors, which is connected to the input/output terminal has a resistance value smaller than that of the resistor connected between the drain electrode and the source electrode of each of the remaining field effect transistors.

2. A radio frequency switching circuit according to claim 1, wherein:
the basic switching section includes n number of field effect transistors (n is an integer of 2 or greater) connected in series; and
expression (1) is fulfilled where Rds(i) is the resistance value of the resistor connected between the drain electrode and the source electrode of the i'th field effect transistor (i is an integer of 1 or greater and n or smaller) from the input/output terminal:
Rds(1)<Rds(2)≦ . . . ≦Rds(n-1)≦Rds(n) (1).

3. A radio frequency switching circuit for controlling a flow of a radio frequency signal, comprising:
a basic switching section including a plurality of field effect transistors connected in series and provided between an input/output terminal for inputting and outputting the radio frequency signal and the ground; and
a plurality of capacitors each having one terminal connected to a drain electrode of a corresponding field effect transistor among the plurality of field effect transistors and having the other terminal connected to a source electrode of the corresponding field effect transistor;
wherein a capacitor among the plurality of capacitors which is connected between the drain electrode and the source electrode of a field effect transistor, among the plurality of field effect transistors, which is connected to the input/output terminal has a capacitance value larger than that of the capacitor connected between the drain electrode and the source electrode of each of the remaining field effect transistors.

4. A radio frequency switching circuit according to claim 3, wherein:
the basic switching section includes n number of field effect transistors (n is an integer of 2 or greater) connected in series; and
expression (2) is fulfilled where Cds(i) is the capacitance value of the capacitor connected between the drain electrode and the source electrode of the i'th field effect transistor (i is an integer of 1 or greater and n or smaller) from the input/output terminal:
Cds(1)>Cds(2)≧ . . . ≧Cds(n-1)≧Cds(n) (2).

5. A radio frequency switching circuit for controlling a flow of a radio frequency signal, comprising:
a basic switching section including a plurality of field effect transistors connected in series and provided between input/output terminals for inputting and outputting the radio frequency signal; and
a plurality of resistors each having one terminal connected to a drain electrode of a corresponding field effect transistor among the plurality of field effect transistors and having the other terminal connected to a source electrode of the corresponding field effect transistor;
wherein where an input/output terminal, among the input/output terminals, to which a signal voltage is inputted when the basic switching section is in an OFF state is an off-time active terminal, a resistor among the plurality of resistors which is connected between the drain electrode and the source electrode of a field effect transistor, among the plurality of field effect transistors, which is connected to the off-time active terminal has a resistance value smaller than that of the resistor connected between the drain electrode and the source electrode of each of the remaining field effect transistors.

6. A radio frequency switching circuit according to claim 5, wherein:
the basic switching section includes n number of field effect transistors (n is an integer of 2 or greater) connected in series; and
expression (3) is fulfilled where Rds(i) is the resistance value of the resistor connected between the drain electrode and the source electrode of the i'th field effect transistor (i is an integer of 1 or greater and n or smaller) from the off-time active terminal:
Rds(1)<Rds(2)≦ . . . ≦Rds(n-1)≦Rds(n) (3).

7. A radio frequency switching circuit for controlling a flow of a radio frequency signal, comprising:
a basic switching section including a plurality of field effect transistors connected in series and provided between input/output terminals for inputting and outputting the radio frequency signal; and
a plurality of capacitors each having one terminal connected to a drain electrode of a corresponding field effect transistor among the plurality of field effect transistors and having the other terminal connected to a source electrode of the corresponding field effect transistor;
wherein where an input/output terminal, among the input/output terminals, to which a signal voltage is inputted when the basic switching section is in an OFF state is an off-time active terminal, a capacitor among the plurality of capacitors which is connected between the drain electrode and the source electrode of a field effect transistor, among the plurality of field effect transistors, which is connected to the off-time active terminal has a capacitance value larger than that of the capacitor connected between the drain electrode and the source electrode of each of the remaining field effect transistors.

8. A radio frequency switching circuit according to claim 7, wherein:
the basic switching section includes n number of field effect transistors (n is an integer of 2 or greater) connected in series; and
expression (4) is fulfilled where Cds(i) is the capacitance value of the capacitor connected between the drain electrode and the source electrode of the i'th field effect transistor (i is an integer of 1 or greater and n or smaller) from the off-time active terminal:
Cds(1)>Cds(2)≧ . . . ≧Cds(n-1)≧Cds(n) (4).

9. A radio frequency switching circuit for controlling a flow of a radio frequency signal, comprising:
a basic switching section including at least one multi-gate field effect transistor and provided between an input/output terminal for inputting and outputting the radio frequency signal and the ground; and
a plurality of resistors each having one terminal connected to a drain electrode or a source electrode of a corresponding multi-gate field effect transistor among the at least one multi-gate field effect transistor and having the other terminal connected to a corresponding inter-gate electrode mesa among a plurality of inter-gate electrode mesas of the at least one multi-gate field effect transistor;
wherein a resistor among the plurality of resistors which is connected to an inter-gate electrode mesa, among the plurality of inter-gate electrode mesas, which is located closest to the input/output terminal has a resistance value smaller than that of the resistor connected to each of the remaining inter-gate electrode mesas.

10. A radio frequency switching circuit according to claim 9, wherein:
the basic switching section includes the at least one multi-gate field effect transistor each including n number of gate electrodes (n is an integer of 2 or greater); and
expression (5) is fulfilled where Rms(i) is the resistance value of the resistor connected to the i'th inter-gate electrode mesa (i is an integer of 1 or greater and n or smaller) from the input/output terminal:
Rms(1)<Rms(2)≦ . . . ≦Rms(n-1)≦Rms(n) (5).

11. A radio frequency switching circuit for controlling a flow of a radio frequency signal, comprising:
a basic switching section including at least one multi-gate field effect transistor and provided between an input/output terminal for inputting and outputting the radio frequency signal and the ground; and
a plurality of capacitors each having one terminal connected to a drain electrode or a source electrode of a corresponding multi-gate field effect transistor among the at least one multi-gate field effect transistor and having the other terminal connected to a corresponding inter-gate electrode mesa among a plurality of inter-gate electrode mesas of the at least one multi-gate field effect transistor;
wherein a capacitor among the plurality of capacitors which is connected to an inter-gate electrode mesa, among the plurality of inter-gate electrode mesas, which is located closest to the input/output terminal has a capacitance value larger than that of the capacitor connected to each of the remaining inter-gate electrode mesas.

12. A radio frequency switching circuit according to claim 11, wherein:
the basic switching section includes the at least one multi-gate field effect transistor each including n number of gate electrodes (n is an integer of 2 or greater); and
expression (6) is fulfilled where Cms(i) is the capacitance value of the capacitor connected to the i'th inter-gate electrode mesa (i is an integer of 1 or greater and n or smaller) from the input/output terminal:
Cms(1)>Cms(2)≧ . . . ≧Cms(n-1)≧Cms(n) (6).

13. A radio frequency switching circuit for controlling a flow of a radio frequency signal, comprising:
a basic switching section including at least one multi-gate field effect transistor and provided between input/output terminals for inputting and outputting the radio frequency signal; and
a plurality of resistors each having one terminal connected to a drain electrode or a source electrode of a corresponding multi-gate field effect transistor among the at least one multi-gate field effect transistor and having the other terminal connected to a corresponding inter-gate electrode mesa among a plurality of inter-gate electrode mesas of the at least one multi-gate field effect transistor;
wherein where an input/output terminal, among the input/output terminals, to which a signal voltage is inputted when the basic switching section is in an OFF state is an off-time active terminal, a resistor among the plurality of resistors which is connected to an inter-gate electrode mesa, among the plurality of inter-gate electrode mesas, which is located closest to the off-time active terminal has a resistance value smaller than that of the resistor connected to each of the remaining inter-gate electrode mesas.

14. A radio frequency switching circuit according to claim 13, wherein:
the basic switching section includes the at least one multi-gate field effect transistor each including n number of gate electrodes (n is an integer of 2 or greater); and
expression (7) is fulfilled where Rms(i) is the resistance value of the resistor connected to the i'th inter-gate electrode mesa (i is an integer of 1 or greater and n or smaller) from the off-time active terminal:
Rms(1)<Rms(2)≦ . . . ≦Rms(n-1)≦Rms(n) (7).

15. A radio frequency switching circuit for controlling a flow of a radio frequency signal, comprising:
a basic switching section including at least one multi-gate field effect transistor and provided between input/output terminals for inputting and outputting the radio frequency signal; and
a plurality of capacitors each having one terminal connected to a drain electrode or a source electrode of a corresponding multi-gate field effect transistor among the at least one multi-gate field effect transistor and having the other terminal connected to a corresponding inter-gate electrode mesa among a plurality of inter-gate electrode mesas of the at least one multi-gate field effect transistor;
wherein where an input/output terminal, among the input/output terminals, to which a signal voltage is inputted when the basic switching section is in an OFF state is an off-time active terminal, a capacitor among the plurality of capacitors which is connected to an inter-gate electrode mesa, among the plurality of inter-gate electrode mesas, which is located closest to the off-time active terminal has a capacitance value larger than that of the capacitor connected to each of the remaining inter-gate electrode mesas.

16. A radio frequency switching circuit according to claim 15, wherein:
the basic switching section includes the at least one multi-gate field effect transistor each including n number of gate electrodes (n is an integer of 2 or greater); and
expression (8) is fulfilled where Cms(i) is the capacitance value of the capacitor connected to the i'th inter-gate electrode mesa (i is an integer of 1 or greater and n or smaller) from the off-time active terminal:
Cms(1)>Cms(2)≧ . . . ≧Cms(n-1)≧Cms(n) (8).

17. A radio frequency switching circuit, comprising a combination of identical or different radio frequency switching circuits each according to claim 1, wherein the flow of a radio frequency signal is optionally switched between a plurality of input/output terminals.

18. A semiconductor device, comprising a radio frequency switching circuit according to claim 1 integrated on a semiconductor substrate.
